(19) United States
(12) Patent Application Publication
(10) Pub. No.: US 2008/0265963 A1
(43) Pub. Date: Oct. 30, 2008

(54) CASCADED PHASE SHIFTER

(75) Inventor: Andreas Bock, Hemmingen (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/109,986

(22) Filed: Apr. 25, 2008

Related U.S. Application Data
(60) Provisional application No. 61/016,669, filed on Dec. 26, 2007.

(30) Foreign Application Priority Data
Apr. 26, 2007 (DE) 10 2007 019 745.6

(51) Int. Cl. H03H 11/26

(52) U.S. Cl. 327/246

(57) ABSTRACT

The invention relates to a phase shifter which has at least two cascaded delay stages (1, 2), each including a first differential pair of bipolar transistors (Q1, Q1′) and a second differential pair of bipolar transistors (Q2, Q2′). The bases of the first differential pair (Q1, Q1′) serve as input nodes for the delay stage. The emitters of the first differential pair are coupled to a first current source (CS1), and their collectors are coupled to respective loads (D1, D1′; R1, R1′) to provide differential output nodes (OUT1, OUT1′) of the delay stage. The bases of the second differential pair (Q2, Q2′) are coupled to respective output nodes of the first differential pair (Q1, Q1′) of a delay stage, and their emitters are coupled to a variable current source (CS21, CS22, . . . ) for selectively adjusting the current (I_{A}, I_{B}, . . . ) through the second differential pair (Q2, Q2′). The input nodes of each following delay stage (2, . . . ) are coupled to the output nodes of a preceding delay stage, and a common load stage is coupled to the collectors of the second differential pairs (Q2, Q2′) of all delay stages to provide a differential output signal, wherein the amount of phase shift of the output signal is adjusted by adjusting the current through the variable current sources (CS21, CS22, . . . ).

This patent application claims priority from German Patent Application No. 10 2007 019 745.6, filed 26 Apr. 2007 and U.S. Provisional Patent Application No. 61/016,669, filed 26 Dec. 2007, the entireties of which are incorporated herein by reference.

### FIELD OF THE INVENTION

The invention relates to a phase shifter; and, more specifically, to a phase shifter having multiple delay stages.

### BACKGROUND

In broadband communication systems, phase shifters with a wide shifting and frequency range are in high demand. For example, such phase shifters are required in the delay adjustment of clock signals in clock recovery systems, channel de-skewing and wave-shaping circuitry, where signals are superimposed with their delayed counterpart to generate an output signal with the desired wave shape. A conventional solution capable of a II/2 phase-shifting range is shown in FIG. 1, see Dawson & Rogerson, “An Undersea Fiber-Optic Regenerator Using an Integral-Substrate Package and Flip-Chip SAW Mounting,” Journal of Lightwave Technology, Vol. LT-2, No. 6, pp. 926-932, December 1984. For the conventional solution, a maximum phase shift of 2 II/3 has been disclosed. However, a reduced phase shift of II/2, rather than 2 II/3, turned out to be more reasonable and proposals were made to extend the range subsequently by means of frequency dividers and frequency doublers. This approach is disclosed in Schmidt & Rein, “The Continuously Variable GHz Phase shifter IC Covering More Than One Frequency Decade,” IEEE Journal of Solid-State Circuits, Vol. 27, No. 6, June 1992. Improvements of the basic phase-shifted stage use a Cherry-Hooper type circuitry and low pass filtering as described in Cherry & Hooper, “The Design of Wide-Band Transistor Feedback Amplifiers,” Proc. IEE, Vol. 110, pp. 375-389, February 1963. A modified phase shifter circuitry using the Cherry-Hooper load is shown in FIG. 2. The emitter degenerated transistor pair Q1, Q1′ for current steering shown in FIG. 1 is not shown in FIG. 2.

The basic principle of a phase shifter resides in superimposing a signal with its delayed (shifted in phase) counterpart. Referring to FIG. 1, applying a sufficiently high positive voltage V_{C} to the lower differential transistors Q1, Q1′ will mostly or completely steer the tail current to the upper left differential pair Q2, Q2′ which is connected to the undelayed input V_{A}. A setting of V_{C}=0 will create an output signal superimposed by both the undelayed input V_{A} and the delayed signal V_{B}. A high negative V_{C} voltage will switch the tail current completely to the upper right differential pair Q3, Q3′ connected to the delayed input V_{B}. Superimposed rectangular input signals may lead to severe signal distortion. A low signal distortion can be achieved by feeding the mixer stage (i.e., the upper two differential switches) with a joint load, with a sinusoidal input signal (low pass filtering) or by filtering the distorted output current of the mixer prior to feeding it to a transimpedance stage (TIS). Both approaches to filter the signal in order to reduce the signal distortion have the drawback of an increased minimum delay (phase shift). Another drawback of the prior art solution results from the manner in which the input signal V_{B} is delayed. The simple low pass filter (RC) or a transmission line will significantly attenuate the high frequency components of the signal and change its shape from rectangular to a more or less sinusoidal one (bandwidth limited signal) and also reduce the amplitude of V_{B}. Superimposing two signals with different shape and amplitude can result in unwanted additional distortion.

### SUMMARY

It is an object of the invention to provide a phase shifter with an adjustable phase of the output signal having lower distortion, lower minimum delay time and high bandwidth.

Accordingly, a phase shifter is provided which includes at least two cascaded delay stages, each comprising a first differential pair of bipolar transistors and a second differential pair of bipolar transistors. In a described embodiment, the bases of the first differential bipolar transistor pair serve as input nodes for the delay stage. The emitters of the first differential pair are coupled to a first current source, and the collectors of the first differential pair are coupled to respective loads to provide differential output nodes of the delay stage. The bases of the second differential pair of bipolar transistors are coupled to the respective output nodes of the first differential pair, and the emitters of the second differential pair are coupled to a variable current source for selectively adjusting the current through the second differential pair. The inputs of each following delay stage are coupled to the output nodes of a preceding delay stage, and a common load stage is coupled to the collector nodes of the second differential pairs of bipolar transistors of all delay stages to provide a differential output signal, wherein the amount of phase shift of the output signal is adjusted by adjusting the current through the second differential pairs by the variable current sources.

So, in one aspect, the invention provides a phase shifter that uses cascaded stages to generate the required delay (phase shift) instead of using a delay line coupled between the inputs of two stages. The delay stages, according to a described embodiment, include respective second pairs of transistors, which are all coupled to the same load stage (transimpedance stage). The load stage superimposes the signals of the delay stages. The second differential pair of each delay stage contributes an output current which is fed to the transimpedance stage. The amount of output current per delay stage defines how much the respective delay stage contributes to the output signal. A higher current contribution of a delay stage, which is positioned later in the cascade of delay stages, results in a greater phase shift (delay) of the output signal with respect to the input signal fed to the first delay stage. A higher contribution of an earlier delay stage in the chain results in less phase shift (delay).

According to another aspect of the invention, the phase shifter may include controlling means to control the delay stages, such that only two adjacent delay stages may be used to define the phase shift (i.e., the second differential pairs of only two adjacent delay stages may be switched on, such that the currents contribute to the output signal, while the other second differential pairs are switched off).

The bases of the second differential pair of bipolar transistors of each delay stage may be either directly connected to respective output nodes of the first differential pair of the same delay stage, or the bases of the second differential pair of bipolar transistors of each delay stage may be coupled through a level shifter to respective output nodes of a preceding delay stage. Further, the delay stages may be connected directly to each other or, as appropriate, by use of level shifters in order to adapt the voltage levels of the output signals to the input signals.

If the cascaded delay stages are directly connected to each other and the second differential pairs (i.e., the bases of the transistors) within the delay stages are also directly connected to the output nodes of the first differential pairs, then the phase shifter benefits from translinear coupling and operates in a current mode. According to this aspect of the invention, there is no need to use bulky (voltage) level shifters between consecutive delay stages as the behavior of the circuit becomes a consequence of current ratios. The input signals (typically, a voltage) may be transferred only once into the current domain (i.e., in the first input stage). The delay stages are inherently linear. Due to the high bandwidth of the current mode connected stages, the phase shifting range covered by two stages is smaller than in prior art (voltage mode) solutions. However, due to the pre-distortion characteristic of the current mode connection, the signal distortion is lower than for the conventional solutions. Therefore, additional filtering to suppress distortion may no longer be necessary; and, in particular, RC-filters for preventing distortion may no longer be necessary, so may be omitted.

According to another aspect of the invention, the cascaded delay stages may be coupled to each other via a resistor, preferably connected between the output node of a preceding delay stage and the base of a transistor of the first differential pair of a subsequent delay stage, such that the resistor and, for example, a parasitic capacitance of the subsequent delay stage constitute an RC network with a low pass filter characteristic. The resistors between the delay stages should be chosen with great care not to introduce additional distortion (i.e., not to impair the equalization effect of the current mode coupling). Also, the transimpedance (load) stage, which is coupled as a common load to the second differential pairs of all delay stages may preferably be implemented as a Cherry-Hooper-style load.

In order to achieve a broader range for the phase shift (delay), a fixed delay stage (or multiple fixed delay stages) having only a single differential pair of transistors (i.e., the first differential pair) can be coupled between two adjacent delay stages. As the minimum delay of a single delay stage is smaller than the minimum delay of a prior art solution, enlarging the range of possible phase shifts is useful.

Another aspect gives a method for providing a phase shift with a phase shifter which is implemented in accordance with the aspects set out hereabove. In an embodiment, the method includes selectively controlling the variable current sources of a plurality of delay stages, such that only the second differential pairs of bipolar transistors of consecutive pairs of delay stages are activated, thereby continuously determining the delay of the phase shifter over the whole shifting range. Accordingly, only two consecutive (either adjacent or separated by a fixed delay stage) delay stages receive sufficient current through the variable current source to contribute to the delay in the superimposed output signal. The remaining second pairs of delay stages are basically idle (i.e., switched off) and do not contribute to the delay. This approach allows power to be saved and the phase shift to be precisely adjusted. In order to save more power, it is possible to switch off even the first pairs of those delay stages which follow the last delay stage having an activated (used) second differential pair. Just the first differential pairs of the delay stages preceding the pair of delay stages being used for the fine tuning of the phase shift (i.e., having activated second differential pairs) are activated.

### BRIEF DESCRIPTION OF THE DRAWINGS

Further aspects of the invention will become apparent from the following detailed description of example embodiments, considered with reference to accompanying drawings wherein:

FIG. 1 (Prior Art) shows a simplified schematic of a phase shifter stage according to the prior art;

FIG. 2 (Prior Art) shows a simplified schematic of a modified phase shifter stage according to the prior art;

FIG. 3 shows a simplified schematic of another modified phase shifter according to a first aspect of the invention;

FIGS. 4A and 4B show two examples for a current mode connected phase shifter according to a second aspect of the invention;

FIG. 5 shows a simplified schematic of an embodiment of a phase shifter according to a third aspect of the invention; and

FIG. 6 shows a simplified schematic of another embodiment of a phase shifter according to a fourth aspect of the invention.

### DETAILED DESCRIPTION OF EXAMPLE EMBODIMENTS

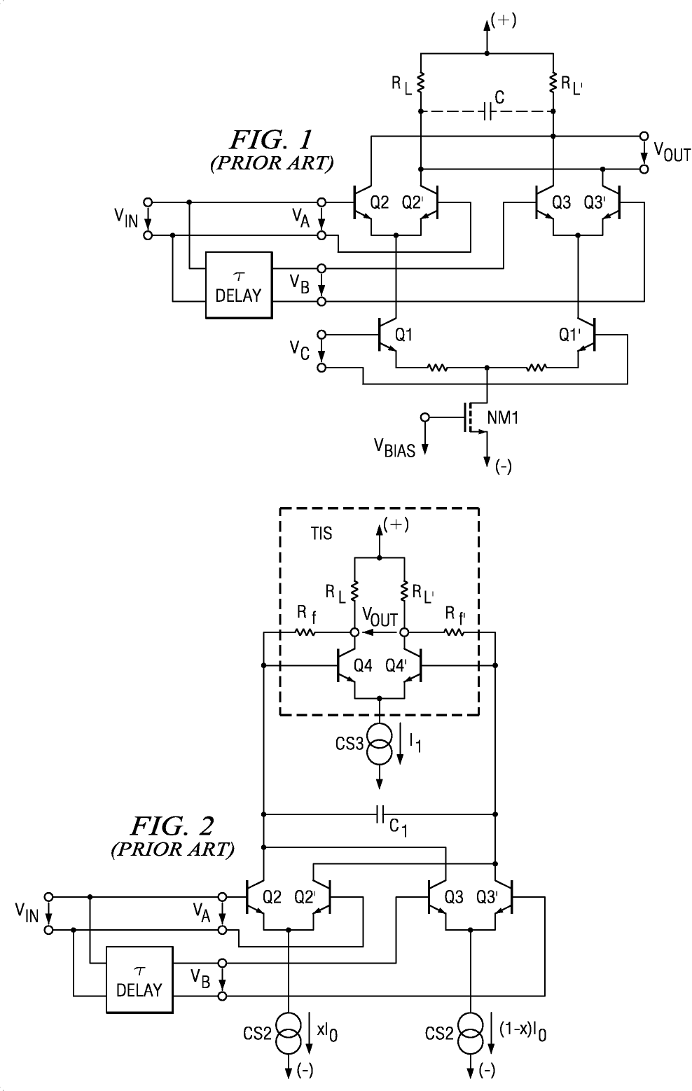

FIG. 1 shows a simplified schematic of a prior art solution of a phase shifter. As shown, the output signal V_{OUT} is a delayed (phase shifted) version of the input signal V_{IN}. The input voltage V_{IN} is coupled to the differential pair Q2, Q2′ and a delayed version V_{B} of the input voltage V_{IN} is coupled to the second differential pair Q3, Q3′. As Q3, Q3′ receives the delayed version V_{B} of the input signal V_{IN}, the amount of phase shift can be controlled by the control voltage V_{C}. V_{C} is coupled to the differential pair Q1, Q1′. A load stage comprises resistors RL, RL′ commonly coupled, respectively, to the collectors of the differential pairs Q2, Q2′ and Q3, Q3′. A current source is implemented by NMOS transistor NM1 having a bias voltage V_{BIAS} to sink a constant current through the differential pair Q1, Q1′. A high positive voltage V_{C} opens transistor Q1 and closes transistor Q1′, to steer all or the major part of the current through differential pair Q2, Q2′. Accordingly, the output voltage V_{OUT} is basically in phase with the input voltage V_{IN}, having a minimum delay due to the inherent delays of the components. A negative voltage V_{C} opens Q1′ and closes transistor Q1 such that the current is steered through differential pair Q3, Q3′ and the output voltage V_{OUT} is dominated by V_{B}.

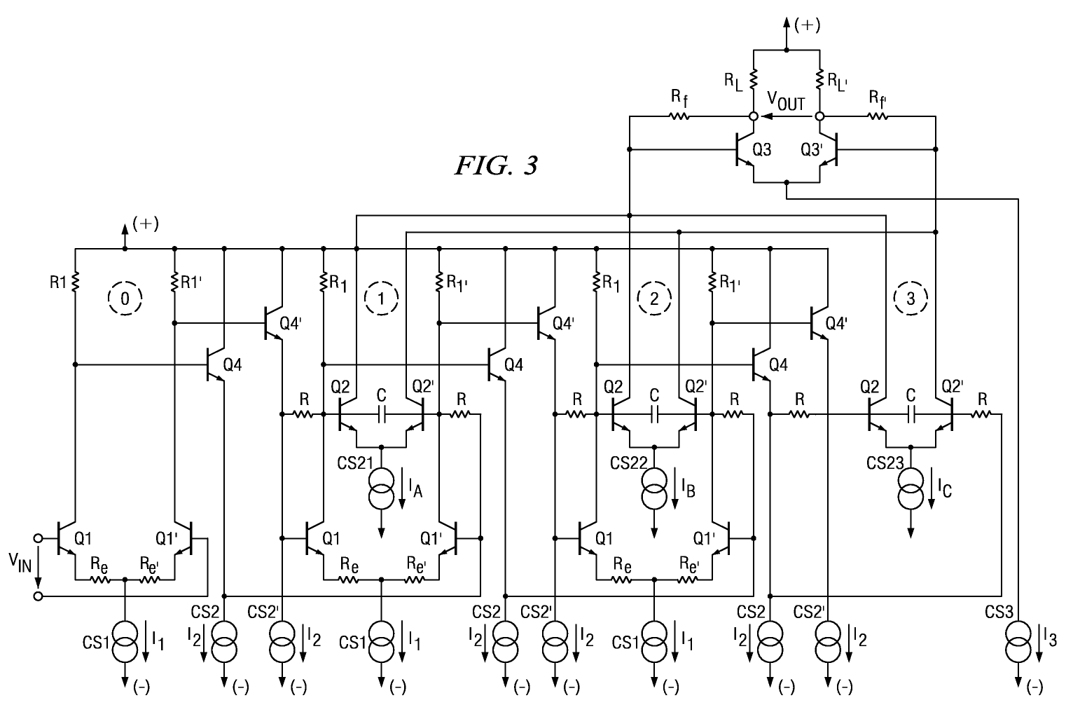

FIG. 2 shows a simplified schematic of a conventional phase shifter with a Cherry-Hooper style transimpedance stage coupled as a common load to the delay stages. Superimposing rectangular input signals in the solution of FIG. 2 will, however, result in considerable distortion. Low signal distortion can be achieved by feeding the differential pairs Q2, Q2′ and Q3, Q3′ with a sinusoidal input signal. This requires low pass filtering of the rectangular input signal. Another approach is to filter the distorted output currents of Q2, Q2′ and Q3, Q3′ (mixer-stage) prior to feeding them to the transimpendance stage TIS. Filtering the signals in order to reduce the signal distortion, however, has the drawback of an increased minimum delay (phase shift).

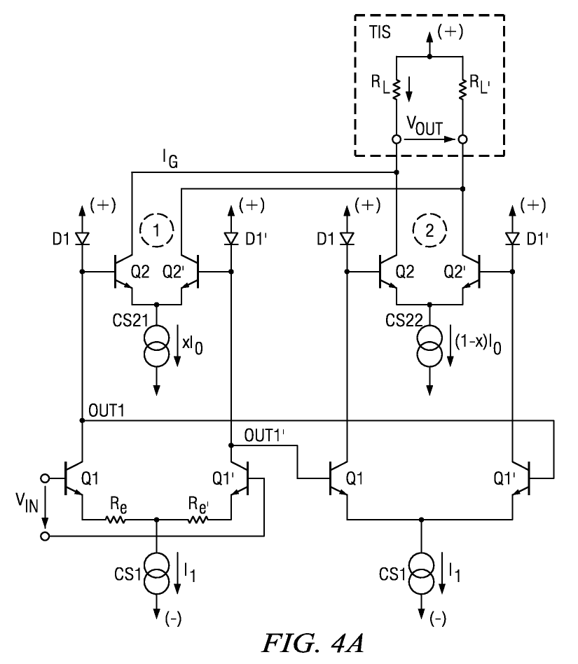

FIG. 3 shows a simplified schematic of a three-stage solution of a phase shifter according to a first aspect of the invention. Instead of two stages coupled by a delay line, there are three consecutive delay stages indicated by a number in a dashed circle (1, 2 and 3), and an input stage indicated by 0. The transadmittance parts of the mixer consist of differential pairs Q2, Q2′, whereas the delay stages have differential pairs Q, Q1′ and resistors Re, Re′. The current sources CS1, CS2, CS2′ and CS3 are constant current sources. The current sources CS21, CS22 and CS23 are variable current sources, respectively providing currents I_{A}, I_{B} and I_{C}. The transimpedance stage TIS comprises load resistors RL, RL′ and Rf, Rf′, and a differential transistor pair Q3, Q3′. The mixer stages are coupled via resistors R and a capacitance C to the delay stages in order to provide a low pass filtering. For I_{A}=I₀, the minimum delay (phase shift) is achieved. For low delay settings (phase shift), the current is steered between stage 1 and stage 2 (I_{A}=[1−x]*I₀ and I_{B}=x*I₀ with x varying from 0 to 1; I_{C}=0) while I_{C} is turned off. For x=1 and greater, the delays are adjusted by distributing the current between stage 2 and stage 3 while the tail current I_{A} is kept close to zero (I_{B}=[1−x]*I₀ and I_{C}=x*I₀ with x varying from 0 to 1; I_{A}=0). Only the tail current of the differential pairs marked with the indicated numbers (dashed circles) are varied or turned off. All other tail currents have fixed values (e.g. I₁). The cascaded stage design based on a common phase shifter as depicted in FIG. 3 has two major drawbacks: It requires power-consuming level shifters Q4, Q4′ (emitter follower, in the example); and the filter increases the minimum adjustable delay (phase shift).

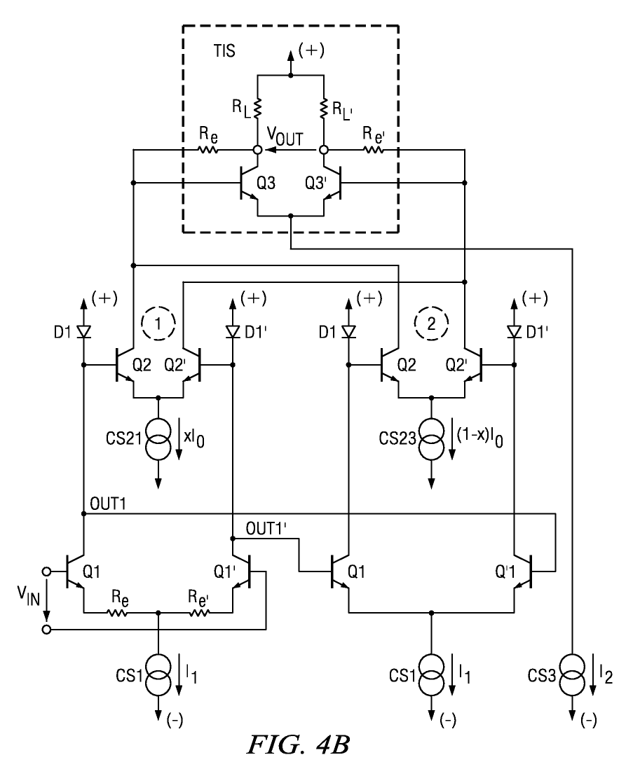

FIGS. 4A and 4B show two different embodiments of a phase shifter according to the invention. The circuit of FIG. 4A has two delay stages 1 and 2 indicated by numbers in circles. Each delay stage comprises a differential pair Q1, Q1∝, a current source CS1 coupled to the differential pair Q1, Q1′, and diode load elements D1, D1′. A second differential pair Q2, Q2′ is coupled to the collectors of the first differential pair Q1, Q1′. A variable current source CS21, CS22 is coupled to the respective differential pair Q2, Q2′. The differential pairs Q2, Q2′ may be considered as the mixer stage or the transadmittance stage of the common load. In FIG. 4A the load coupled to all mixer stages comprises two resistors RL, RL′. By adjusting the currents x I₀ and (1−x) I₀ of the current sources CS21 and CS22, the phase shift of the output signal V_{OUT} is shifted between a minimum and a maximum value. The resistors Re, Re′ coupled to the emitters of the first differential pair Q1, Q1′ of the input stage serve to linearize the input signal and to reduce distortion of the superimposed input signals. The amplification of the input stage is reduced, the bandwidth increased and the delay of the input stage is also reduced by using the resistors Re, Re′. The second delay stage operates in linear mode due to the transistors in common base connection. Translinear coupling is provided by directly coupling of the bases of the first differential pair transistors Q1, Q1′ of the second delay stage 2 to the output nodes OUT1, OUT1′ of the first delay stage 1, and directly coupling the bases of the second differential pair transistors Q2, Q2′of each delay stage 1,2, such that the delay stages operate in a current mode. Accordingly, the delay stages are inherently linear and the need for RC-filtering to suppress distortions is avoided. The bulky and power consuming level shifters (Q4, Q4′ in FIG. 3) of the circuit shown in FIG. 3 can also be omitted.

FIG. 4B shows a simplified schematic of another embodiment of the invention. The delay stages 1, 2 have basically the same components as shown in FIG. 4A and the basic functionality is the same. The embodiment of FIG. 4B has a transimpedance stage that is implemented in a Cherry-Hooper style. The common load coupled to all delay stages comprises a differential pair Q3, Q3′, the load resistors RL, RL′, and resistors Re, Re′.

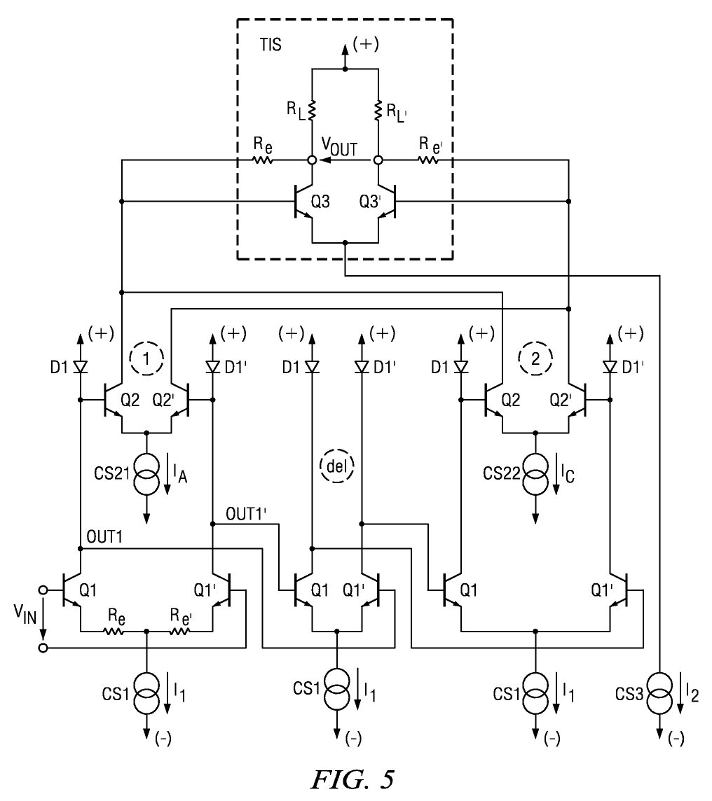

FIG. 5 shows a simplified schematic of another embodiment of the invention. In order to avoid a high count of cascaded stages or inputs for the phase shifter, additional delay stages may be inserted as depicted in FIG. 5. The delay stage indicated by “del” in a dashed circle is used to introduce an additional delay between the delay stages 1 and 2. According to an aspect of the invention, it is suggested to cascade delay stages instead of using RC-delay elements or delay lines between the delay stages.

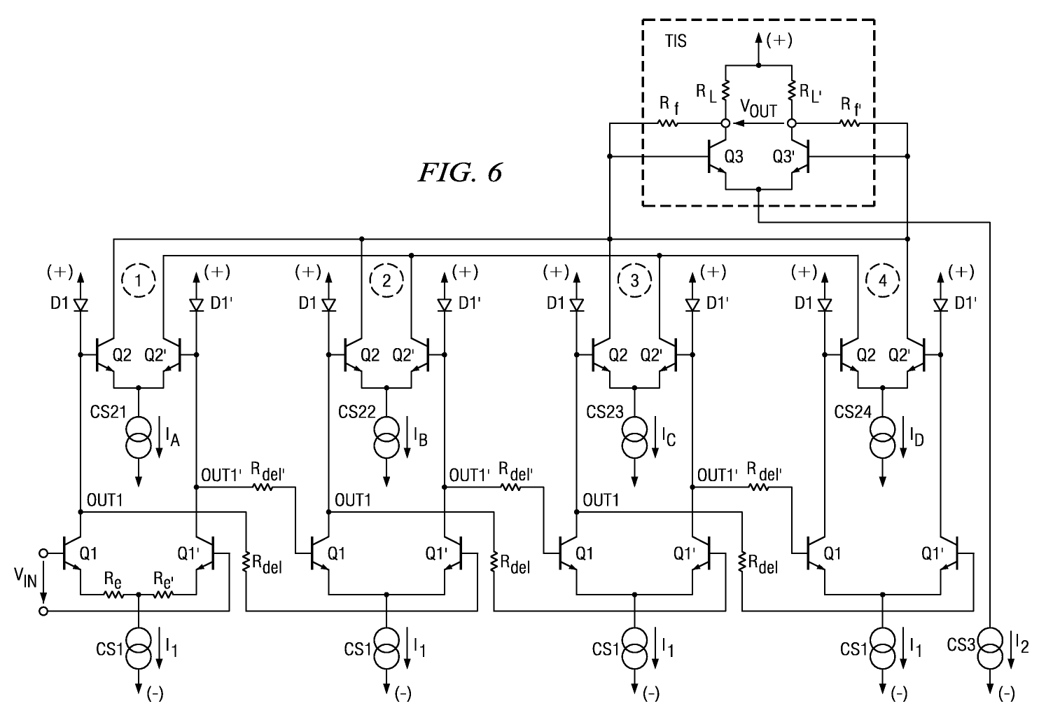

FIG. 6 shows a simplified schematic of an embodiment according to the invention that has four cascaded delay stages 1, 2, 3 and 4. The differential pairs Q1, Q1′ and Q2, Q2′ of each delay stage are coupled to each other in a current mode manner. The current sources CS1 and CS3 provide a constant current, whereas the current sources CS21, CS22, CS23 and CS24 are variable current sources providing the currents I_{A}, I_{B}, I_{C} and I_{D}, respectively. The respective output currents of the differential pairs Q2, Q2′ of each delay stage (the mixer stage) are combined in the transimpedance stage TIS, implemented in a Cherry-Hooper style. By coupling the outputs of each preceding delay stage to the subsequent delay stage via an additional resistor R_{del}, R_{del}′, an additional delay can be introduced. The resistors should, however, be dimensioned with great care in order to not produce additional distortion. According to one possible configuration, only two adjacent delay stages may be used to adjust the phase shift. In this case, for small phase shifts, only the currents I_{A}, and I_{B} are tuned and currents I_{C} and I_{D} are switched off. For greater phase shifts, only the currents I_{B}, and I_{C} are adjusted and currents I_{D} and I_{A} are switched off. Finally, for maximum phase shift, I_{C} and I_{D} may be used and I_{A}, and I_{B} may be turned off. Such procedure of controlling the four currents I_{A}, I_{B}, I_{C} and I_{D} in order to provide only a pair-wise contribution of the delay stages to the total phase shift can be implemented by a specific control stage. If the phase shift or delay is defined by the delay stage 2 and 3 (currents I_{B}, I_{C}), the first differential pair Q1, Q1′ of the first delay stage 1 must be correctly biased, i.e., switched on, as the delay of the first stage contributes to the total delay. Yet, the delay stage 4 may be switched off or put in a power-down mode, as this delay stage does not contribute to the total delay.

Those skilled in the art to which the invention relates will appreciate that the described implementations are merely illustrative example embodiments, and that there are many other embodiments and variations of embodiments that can be implemented within the scope of the claimed invention.

What is claimed is:

1. A phase shifter comprising:
at least two cascaded delay stages, each comprising a first differential pair of bipolar transistors and a second differential pair of bipolar transistors;
the bases of the first differential pair of bipolar transistors serving as input nodes for the delay stage, the emitters of the first differential pair being coupled to a first current source, and the collectors of the first differential pair being coupled to respective loads to provide differential output nodes of the delay stage;
the bases of the second differential pair of bipolar transistors being coupled to respective output nodes of a first differential pair of a delay stage, and the emitters of the second differential pair being coupled to a variable current source for selectively adjusting the current through the second differential pair; and
the input nodes of each following delay stage being coupled to the output nodes of a preceding delay stage;
and further comprising:
a common load stage coupled to the collectors of the second differential pairs of bipolar transistors of all delay stages to provide a differential output signal;
wherein the amount of phase shift of the output signal is adjusted by adjusting the current through the variable current sources.

2. The phase shifter according to claim 1, wherein the bases of the second differential pair of bipolar transistors of each delay stage are directly connected to respective output nodes of the first differential pair of the same delay stage.

3. The phase shifter according to claim 2, wherein the respective bases of the first differential pair of a following delay stage are directly connected to the output nodes of a preceding delay stage.

4. The phase shifter according to claim 1, wherein the respective bases of the first differential pair of a following delay stage are directly connected to the output nodes of a preceding delay stage.

5. The phase shifter according to claim 1, wherein the bases of the second differential pair of bipolar transistors of each delay stage are coupled through a level shifter to respective output nodes of a preceding delay stage.

6. The phase shifter according to claim 5, wherein the respective bases of the first differential pair of a subsequent delay stage are coupled through the level shifter to the output nodes of a preceding delay stage.

7. The phase shifter according to claim 1, comprising multiple cascaded delay stages adapted and configured for selectively controlling the variable current sources of the plurality of delay stages, such that only second differential pairs of bipolar transistors of consecutive pairs of delay stages are switched on.

8. The phase shifter according to claim 1, wherein a resistor is coupled between an output node of a preceding delay stage and the base of a transistor of the first differential pair of a subsequent delay stage, such that the resistor and a parasitic capacitance of the subsequent delay stage constitute an RC network with a low pass filter characteristic.

9. The phase shifter of claim 1, wherein the common load stage is a Cherry-Hooper style load.

10. The phase shifter of claim 1, wherein a fixed delay stage having only a single differential pair of transistors is coupled between two adjacent delay stages.

11. A method of operating a phase shifter,
the phase shifter comprising:
at least two cascaded delay stages, each comprising a first differential pair of bipolar transistors and a second differential pair of bipolar transistors;
the bases of the first differential pair of bipolar transistors serving as input nodes for the delay stage, the emitters of the first differential pair being coupled to a first current source, and the collectors of the first differential pair being coupled to respective loads to provide differential output nodes of the delay stage;
the bases of the second differential pair of bipolar transistors being coupled to respective output nodes of a first differential pair of a delay stage, and the emitters of the second differential pair being coupled to a variable current source for selectively adjusting the current through the second differential pair; and
the input nodes of each following delay stage being coupled to the output nodes of a preceding delay stage;
and further comprising:
a common load stage coupled to the collectors of the second differential pairs of bipolar transistors of all delay stages to provide a differential output signal;
wherein the amount of phase shift of the output signal is adjusted by adjusting the current through the variable current sources;
and the method comprising selectively controlling the variable currents sources of a plurality of delay stages, such that only adjacent pairs of delay stages are activated at one time.
